(19) United States
(12) Patent Application Publication
(10) Pub. No.: US 2025/0331132 A1
(43) Pub. Date: Oct. 23, 2025

(54) HEAT RADIATION BODY AND BOX-SHAPED BODY

(71) Applicant: YAZAKI CORPORATION, Tokyo (JP)

(72) Inventors: Hirotaka KURITA, Makinohara-shi (JP); Keisuke OZAWA, Makinohara-shi (JP); Minoru KUBOTA, Makinohara-shi (JP); Takuya NAKAYAMA, Tokyo (JP)

(73) Assignee: YAZAKI CORPORATION, Tokyo (JP)

(21) Appl. No.: 19/091,222

(22) Filed: Mar. 26, 2025

(30) Foreign Application Priority Data
Apr. 22, 2024 (JP) 2024-069093

(51) Int. Cl. H05K 7/20

(52) U.S. Cl. CPC H05K 7/20409; H05K 7/20854

(57) ABSTRACT

A heat radiation body that radiates heat generated by a heat source, the heat radiation body includes: a base portion to which the heat is transferred; a plurality of heat radiation fins provided on the base portion and extending in a prescribed extending direction; and a wall adjacent to the plurality of heat radiation fins in the extending direction. The plurality of heat radiation fins includes two or more heat radiation fins configured such that an interval between the heat radiation fins and the wall in the extending direction increases toward one end of the wall in an intersecting direction intersecting the extending direction.

### CROSS-REFERENCE TO RELATED APPLICATION(S)

This application is based upon and claims the benefit of priority from prior Japanese patent application No. 2024-069093 filed on Apr. 22, 2024, the entire contents of which are incorporated herein by reference.

### BACKGROUND

### 1. Field of the Invention

The present disclosure relates to a heat radiation body that radiates heat generated by a heat source, and a box-shaped body including the heat radiation body as at least a part of an outer wall.

### 2. Description of the Related Art

An electric junction box to be mounted on a vehicle or the like has been proposed in

the related art. For example, an electric junction box in the related art accommodates electronic components, busbars, and the like in an internal space thereof to prevent accidental touch with the electronic components and the like (for example, see JP2013-240217A).

The above-described type of electric junction box may include heat radiation fins for radiating heat generated by the electronic components during operation to outside. When, for example, a power input terminal that electrically connects inside and outside of the electric junction box for power supply is provided in a vicinity of the heat radiation fins, however, the power input terminal itself or a seat portion that fixes the power input terminal hinders a flow of air flowing along the heat radiation fins, which may impair a heat radiation performance of the electric junction box. It is desirable to improve the heat radiation performance of the electric junction box from a viewpoint of appropriately operating the electric junction box. As understood from the above description, it is desirable to improve the heat radiation performance not only in the electric junction box but also in a box-shaped body that can accommodate a heat source in an internal space. For such reasons, there is a demand for a heat radiation body that has an excellent heat radiation performance and can be applied to a box-shaped body.

### SUMMARY

An object of the present disclosure is to provide a heat radiation body having an excellent heat radiation performance and a box-shaped body including the heat radiation body.

To achieve the above object, a heat radiation body and a box-shaped body according to the present disclosure have following features.

According to an aspect of the present disclosure, there is provided a heat radiation body that radiates heat generated by a heat source, the heat radiation body including: a base portion to which the heat is transferred; a plurality of heat radiation fins provided on the base portion and extending in a prescribed extending direction; and a wall adjacent to the plurality of heat radiation fins in the extending direction, in which the plurality of heat radiation fins includes two or more heat radiation fins configured such that an interval between the heat radiation fins and the wall in the extending direction increases toward one end of the wall in an intersecting direction intersecting the extending direction.

According to another aspect of the present disclosure, there is provided a box-shaped body for accommodating a heat source in an internal space, the box-shaped body including: the heat radiation body as at least a part of an outer wall of the box-shaped body.

According to the heat radiation body of the present disclosure, the interval between the wall adjacent to the plurality of heat radiation fins and at least a part of the plurality of heat radiation fins (that is, two or more heat radiation fins) increases toward one end of the wall. Accordingly, when air flows from a flow path between the two or more heat radiation fins to the region between the wall and the two or more heat radiation fins, pressure in a region having a large interval is generally lower than pressure in a region having a small interval. Accordingly, the air flows from the region having a small interval toward the region having a large interval (that is, toward one end of the wall). In other words, the air does not flow to simply collide with the wall, but is guided to flow around one end of the wall. For this reason, even when the wall is present in a vicinity of the heat radiation fins, the flow of air is less likely to be hindered by the wall. Therefore, for example, even when a wall used for a seat portion or the like for fixing a power input terminal and the heat radiation fins are integrally provided on the base portion and are in close contact with each other, heat can be efficiently dissipated from the heat radiation fins. Therefore, the heat radiation body of the present disclosure has an excellent heat radiation performance.

According to the box-shaped body of the present disclosure, the heat radiation body is provided as at least a part of an outer wall of the box-shaped body. Accordingly, heat generated by the heat source inside the box-shaped body can be efficiently radiated to outside of the box-shaped body. Therefore, the box-shaped body of the present disclosure has an excellent heat radiation performance.

The present disclosure has been briefly described above. Details of the present disclosure will be clarified by reading modes for carrying out the invention described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a perspective view illustrating a box-shaped body according to an embodiment of the present disclosure;

FIG. 2 is a perspective view of the box-shaped body in FIG. 1 as viewed from a rear side;

FIG. 3 is an exploded perspective view of the box-shaped body in FIG. 1;

FIG. 4 is a top view of an enlarged portion A in FIG. 3; and

FIG. 5 is a perspective view of a periphery of a seat portion and a bolt attachment portion included in the portion A in FIG. 3 as viewed obliquely from a rear lower side.

### DETAILED DESCRIPTION OF THE INVENTION

### Embodiments

Hereinafter, a box-shaped body 1 according to an embodiment of the present disclosure will be described with reference to the drawings. The box-shaped body 1 accommodates various electronic components such as a relay and a fuse therein, and thus the box-shaped body 1 can also be referred to as an electronic component unit or an electric junction box.

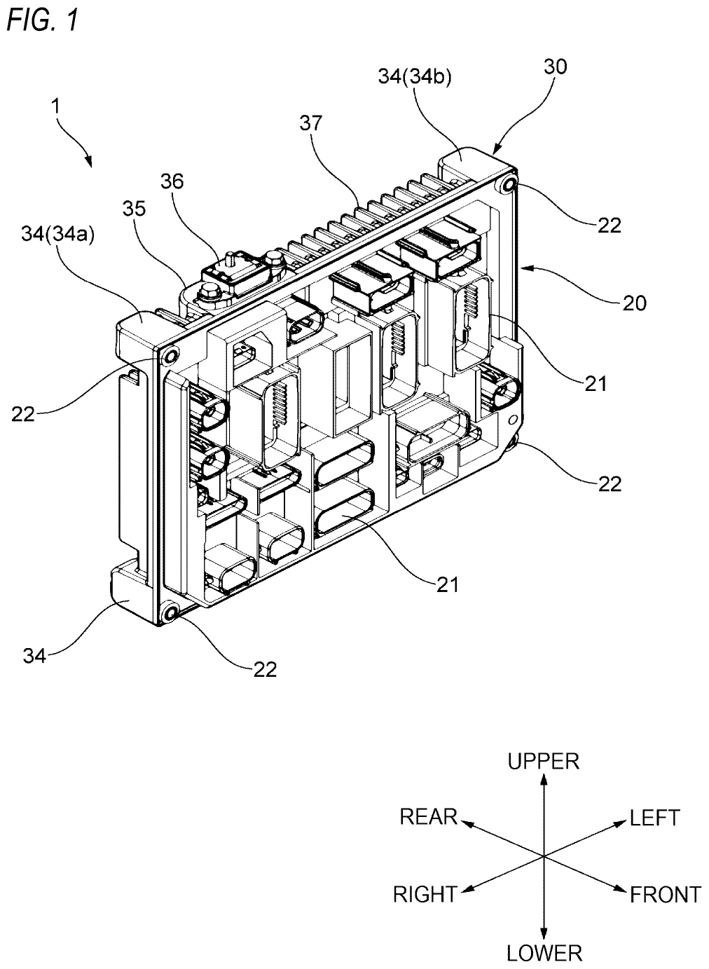

As illustrated in FIGS. 1 to 3, the box-shaped body 1 includes a circuit board 10, and a cover 20 and a case 30 that vertically sandwich the circuit board 10 and define an accommodating space for accommodating the circuit board 10. The box-shaped body 1 is typically attached to a dash panel that separates an engine room and a vehicle interior (cabin) of a vehicle, and is used in a state in which the cover 20 is exposed to the engine room of the vehicle. The case 30 corresponds to a “case” in the present disclosure. The cover 20 corresponds to a “cover” in the present disclosure.

Hereinafter, for convenience of description, “front”, “rear”, “upper”, “lower”, “left”, “right”, a “front-rear direction”, an “upper-lower direction”, and a “left-right direction” are defined as illustrated in FIG. 1. The “front-rear direction”, the “upper-lower direction”, and the “left-right direction” are orthogonal to one another. The upper-lower direction corresponds to a “direction in which heat radiation fins extend” of the present disclosure, and the left-right direction corresponds to a “direction intersecting the direction in which the heat radiation fins extend” of the present disclosure. As will be described later, it is desirable that an upper-lower direction of a vehicle or the like when the box-shaped body 1 is mounted on the vehicle or the like coincides with the “upper-lower direction” in the present example from a viewpoint of smoothly flowing air along heat radiation fins 37. However, the “upper-lower direction” in the present example does not necessarily correspond to the upper-lower direction of the vehicle or the like when the box-shaped body 1 is mounted on the vehicle or the like. Hereinafter, components constituting the box-shaped body 1 will be described.

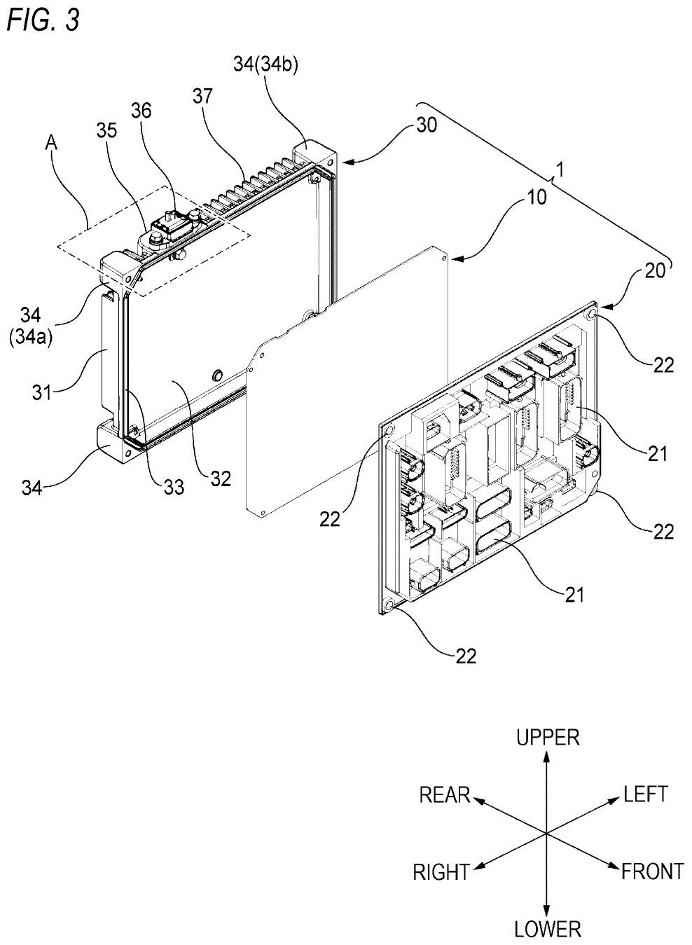

First, the circuit board 10 will be described. The circuit board 10 is, for example, a printed circuit board (PCB) on which various electronic components (not illustrated) such as a relay and a fuse are installed, and has a rectangular flat plate shape in the present example as illustrated in FIG. 3.

Next, the cover 20 will be described. The cover 20 is a resin molded body and has a substantially rectangular flat plate shape as illustrated in FIG. 3. The cover 20 constitutes a part of an outer wall of the box-shaped body 1. A connector 21 including a tubular portion extending forward (toward outside of the box-shaped body 1) is provided at each of a plurality of positions on a front face (face exposed to the outside of the box-shaped body 1) of the cover 20. Each connector 21 accommodates a metal terminal (not illustrated) electrically connected to a corresponding electronic component installed on the circuit board 10. Each connector 21 is fitted to a counterpart connector (not illustrated) connected to an end of an electric wire extending from a device (not illustrated) outside the box-shaped body 1. Accordingly, each connector 21 has a function of electrically connecting an electronic component installed on the circuit board 10 inside the box-shaped body 1 and a device outside the box-shaped body 1. Each connector 21 can be fitted to the counterpart connector in a watertight manner, and has a waterproof function of preventing water from entering from outside when fitted to the counterpart connector. The cover 20 is provided with, in each of four corners of a peripheral edge thereof, a bolt insertion hole 22 running in a plate thickness direction (front-rear direction) of the cover 20.

Next, the case 30 will be described. The case 30 is made of metal (more specifically, die cast aluminum), and also functions as a so-called heat sink that absorbs heat generated from various electronic components installed on the circuit board 10 and releases the heat to the outside. In the present example, as illustrated in FIG. 3, the case 30 integrally has a peripheral wall 31 having a substantially rectangular tubular shape extending in the front-rear direction and a bottom wall 32 having a substantially rectangular flat plate shape and blocking a rear end opening of the peripheral wall 31, and has a substantially rectangular box shape with an open front end. The case 30 (=peripheral wall 31+bottom wall 32) constitutes a part of the outer wall of the box-shaped body 1. The circuit board 10 is placed on an inner face (front face) of the bottom wall 32 and fixed by fastening or the like. Here, the case 30 corresponds to a “heat radiation body” of the present disclosure, and the bottom wall 32 corresponds to a “base portion” of the present disclosure.

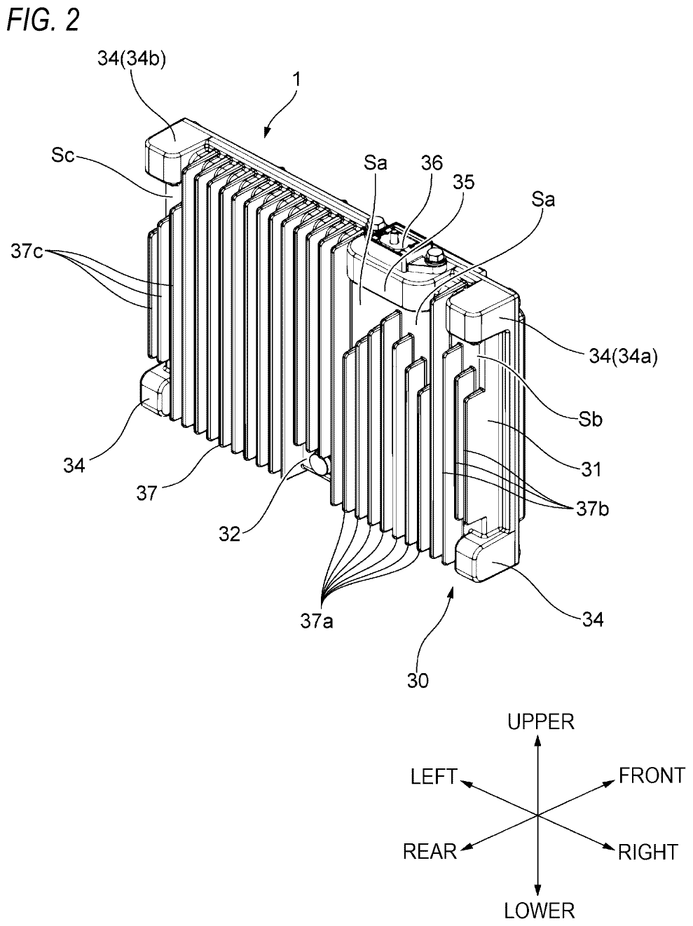

The peripheral wall 31 is formed with, on a substantially rectangular frame-shaped end face on an opening side (front side) thereof, a substantially rectangular annular recessed strip portion 33 that is recessed rearward and extends in a circumferential direction over an 15 entire circumference of the peripheral wall 31. A sealing material (liquid gasket or the like) is injected into the recessed strip portion 33. As illustrated in FIG. 2 and the like, the case 30 is provided with, on the peripheral wall 31 and the bottom wall 32 at each of the four corners of the peripheral edge of the case 30, a bolt attachment portion 34 having an outer shape protruding to a rear side (outer side of the box-shaped body 1) from the bottom wall 32. The bolt attachment portion 34 corresponds to each of the four bolt insertion holes 22 of the cover 20. The bolt attachment portion 34 is formed therein with a female thread that opens to a front side (toward the cover 20). The cover 20 is placed on the end face on the opening side of the peripheral wall 31 to block a front end opening of the case 30, and is fastened to the case 30 by screwing a bolt (not illustrated) inserted into the bolt insertion hole 22 into the female thread of the corresponding bolt attachment portion 34. When the cover 20 is assembled to the case 30, the sealing material injected into the recessed strip portion 33 seals a gap between peripheral edges of the cover 20 and the case 30 fixed to each other, implementing a function of preventing water from entering the box-shaped body 1 from the outside. Hereinafter, for convenience of description, one of four bolt attachment portions 34 which is located at an upper right corner of the case 30 is referred to as a “bolt attachment portion 34a”, and one located at an upper left corner of the case 30 is referred to as a “bolt attachment portion 34b”. The bolt attachment portion 34 can also be used as a position for attaching a jig (so-called bracket) for mounting the box-shaped body 1 on a vehicle or the like.

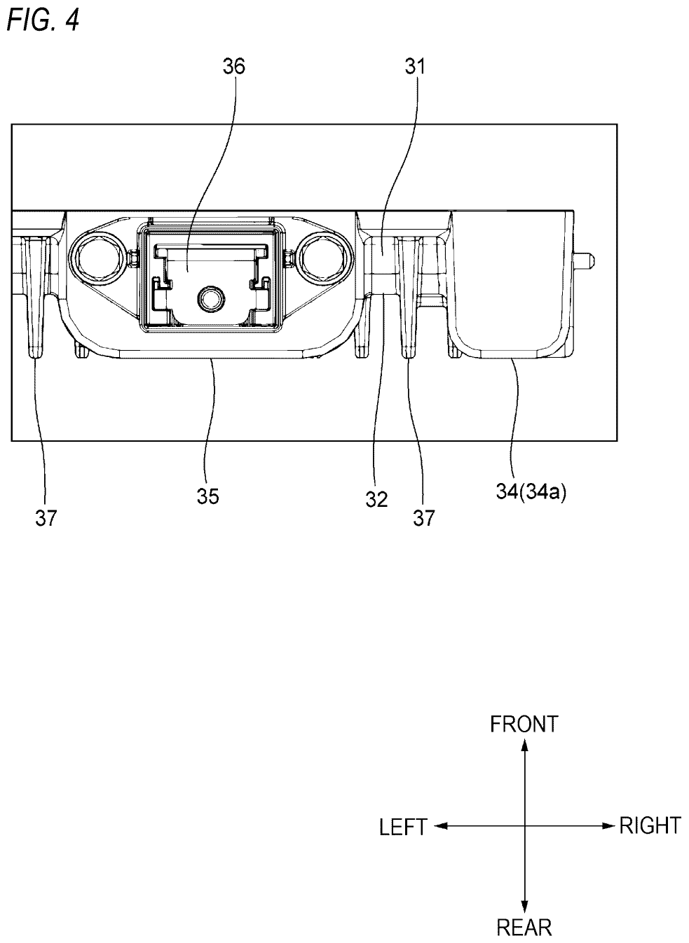

As illustrated in FIGS. 2 to 4 and the like, the case 30 is provided with, on the peripheral wall 31 and the bottom wall 32 in a position close to a left side of the bolt attachment portion 34a on an upper edge extending in the left-right direction, a seat portion 35 having an outer shape protruding to the rear side (outer side of the box-shaped body 1) from the bottom wall 32. A power input terminal 36 electrically connected to various electronic components installed on the circuit board 10 is fixed to the seat portion 35. A mating terminal (not illustrated) provided at an end of an electric wire extending from a power supply (not illustrated) outside the box-shaped body 1 is connected to the power input terminal 36. Accordingly, power supplied from the power supply is supplied to various electronic components installed on the circuit board 10 through the power input terminal 36. Here, the bolt attachment portions 34a and 34b correspond to a “wall” and an “attachment portion” of the present disclosure, and the seat portion 35 corresponds to a “wall” and a “seat portion” of the present disclosure.

As illustrated in FIG. 2 and the like, the case 30 is provided with, in a region of a substantially rectangular rear face (outer face of the box-shaped body 1) of the bottom wall 32 excluding arrangement positions of convex portions such as the four bolt attachment portions 34 and the seat portion 35 that protrude to the outer side (rear side) from the bottom wall 32, a plurality of heat radiation fins 37 extending in the upper-lower direction at equal intervals in the left-right direction. The heat radiation fins 37 have a function of improving a heat radiation performance of the case 30 that functions as a heat sink.

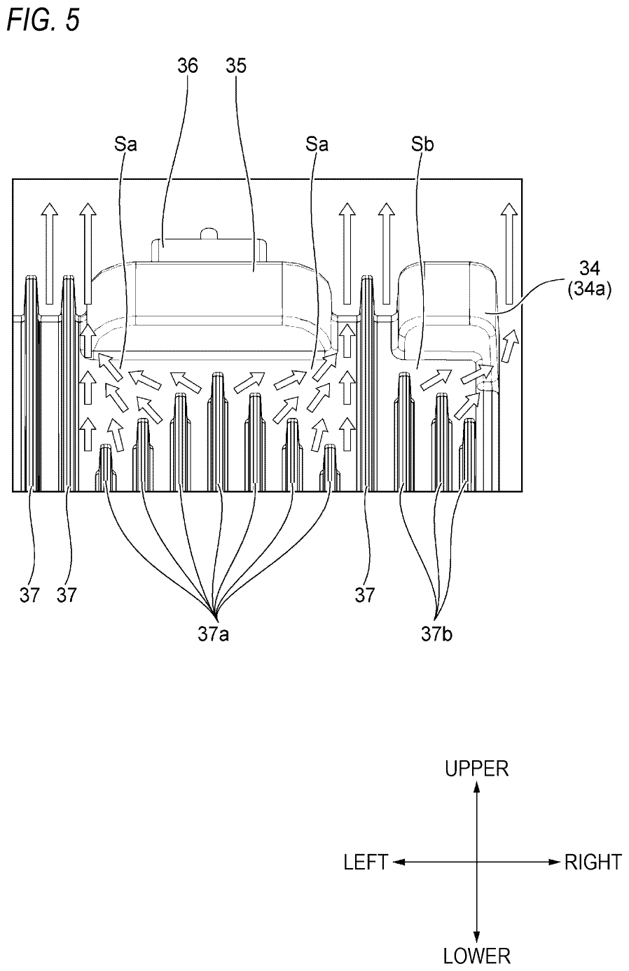

Hereinafter, for convenience of description, two or more (seven in the present example) of the plurality of heat radiation fins 37 which are located below the seat portion 35 protruding to an outer side from the upper edge of the bottom wall 32 and are adjacent to (face) a lower face of the seat portion 35 in the upper-lower direction are referred to as “heat radiation fins 37a” (see FIGS. 2 and 5), two or more (three in the present example) heat radiation fins 37 which are located below the bolt attachment portion 34a protruding to the outer side from the upper edge of the bottom wall 32 and are adjacent to (face) a lower face of the bolt attachment portion 34a in the upper-lower direction are referred to as “heat radiation fins 37b” (see FIGS. 2 and 5), and two or more (three in the present example) heat radiation fins 37 which are located below the bolt attachment portion 34b protruding to the outer side from the upper edge of the bottom wall 32 and are adjacent to (face) a lower face of the bolt attachment portion 34b in the upper-lower direction are referred to as “heat radiation fins 37c” (see FIG. 2).

Upper ends of the seven heat radiation fins 37a are close to the lower face of the seat portion 35, and positions thereof in the upper-lower direction are different from each other. Specifically, as illustrated in FIGS. 2 and 5, the upper ends of the seven heat radiation fins 37a are arranged such that the upper end of the heat radiation fin 37a located at a center of the seat portion 35 in the left-right direction is located on an uppermost side, and the upper ends of the heat radiation fins 37a are located lower positions of the heat radiation fins 37a approach from the center toward left and right ends of the seat portion 35 in the left-right direction. In other words, a region Sa between the seven heat radiation fins 37a and the seat portion 35 in the upper-lower direction has an increasing interval in the upper-lower direction from the center toward the left and right ends of the seat portion 35 in the left-right direction.

Upper ends of the three heat radiation fins 37b are close to the lower face of the bolt attachment portion 34a, and positions thereof in the upper-lower direction are different from each other. Specifically, as illustrated in FIGS. 2 and 5, the upper ends of the three heat radiation fins 37b are arranged such that the upper end of the heat radiation fin 37b located at a left end of the bolt attachment portion 34a in the left-right direction is located on an uppermost side, and the upper ends of the heat radiation fins 37b are located lower as positions of the heat radiation fins 37b approach from the left end toward a right end of the bolt attachment portion 34a in the left-right direction. In other words, a region Sb between the three heat radiation fins 37b and the bolt attachment portion 34a in the upper-lower direction has an increasing interval in the upper-lower direction from the left end toward the right end of the bolt attachment portion 34a in the left-right direction.

Upper ends of the three heat radiation fins 37c are close to the lower face of the bolt attachment portion 34b, and positions thereof in the upper-lower direction are different from each other. Specifically, as illustrated in FIG. 2, the upper ends of the three heat radiation fins 37c are arranged such that the upper end of the heat radiation fin 37c located at a right end of the bolt attachment portion 34b in the left-right direction is located on an uppermost side, and the upper ends of the heat radiation fins 37c are located lower positions of the heat radiation fins 37c approach from the right end toward a left end of the bolt attachment portion 34b in the left-right direction. In other words, a region Sc (see FIG. 2) between the three heat radiation fins 37c and the bolt attachment portion 34b in the upper-lower direction has an increasing interval in the upper-lower direction from the right end toward the left end of the bolt attachment portion 34b in the left-right direction.

Hereinafter, effects of configurations of the intervals of the regions Sa, Sb, and Sc in the upper-lower direction will be described. Heat generated from various electronic components installed on the circuit board 10 is absorbed by the peripheral wall 31 and the bottom wall 32 of the case 30 functioning as a heat sink, and is released to the outside via outer surfaces of the peripheral wall 31 and the bottom wall 32. At this time, air in gaps between the plurality of heat radiation fins 37 receives heat released from the outer surfaces of the bottom wall 32 and the heat radiation fins 37, and thereby has a higher temperature (that is, a relatively lower density) than surrounding air, and thus flows upward along the heat radiation fins 37 extending in the upper-lower direction.

Among the plurality of heat radiation fins 37, air flowing upward through the gaps between the heat radiation fins 37 other than the heat radiation fins 37a, 37b, and 37c (that is, the heat radiation fins 37 provided with no convex portion such as the bolt attachment portion 34 or the seat portion 35 above) can move to above the bottom wall 32 (that is, above the box-shaped body 1) without being hindered from flowing upward from the upper ends of the heat radiation fins 37.

On the other hand, air flowing upward through the gaps between the heat radiation fins 37a may be hindered from flowing upward from the upper ends of the heat radiation fins 37a due to collision with the seat portion 35 or the like. In this regard, in the present example as described above, the region Sa between the seven heat radiation fins 37a and the seat portion 35 has an increasing interval in the upper-lower direction from the center toward the left and right ends of the seat portion 35 in the left-right direction. For this reason, as illustrated in FIG. 5, when air flowing upward through the gaps between the heat radiation fins 37a flows into the region Sa, pressure in a part where the interval of the region Sa in the upper-lower direction is large is generally lower than pressure in a part where the interval of the region Sa in the upper-lower direction is small, and thus the air flows toward a region where the interval of the region Sa in the upper-lower direction is larger. Specifically, the air flowing into the region Sa on a left side of the center of the seat portion 35 in the left-right direction does not flow to simply collide with the seat portion 35, but is guided to flow around the left end of the seat portion 35 as indicated by white arrows in the drawing. Similarly, the air flowing into the region Sa on a right side of the center of the seat portion 35 in the left-right direction does not flow to simply collide with the seat portion 35, but is guided to flow around the right end of the seat portion 35 as indicated by white arrows in the drawing. For this reason, even when the seat portion 35 is present in a vicinity of the upper ends of the heat radiation fins 37a, the upward flow of the air flowing into the region Sa is less likely to be hindered, and thus the heat radiation performance is less likely to be hindered.

Similarly, air flowing upward through the gaps between the heat radiation fins 37b may be hindered from flowing upward from the upper ends of the heat radiation fins 37b due to collision with the bolt attachment portion 34a or the like. In this regard, in the present example as described above, the region Sb between the three heat radiation fins 37b and the bolt attachment portion 34a has an increasing interval in the upper-lower direction from the left end toward the right end of the bolt attachment portion 34a in the left-right direction. For this reason, as illustrated in FIG. 5, when air flowing upward through the gaps between the heat radiation fins 37b flows into the region Sb, pressure in a part where the interval of the region Sb in the upper-lower direction is large is generally lower than pressure in a part where the interval of the region Sb in the upper-lower direction is small, and thus the air flows toward a region where the interval of the region Sb in the upper-lower direction is larger. Specifically, the air flowing into the region Sb does not flow to simply collide with the bolt attachment portion 34a, but is guided to flow around the right end of the bolt attachment portion 34a as indicated by white arrows in the drawing. For this reason, even when the bolt attachment portion 34a is present in a vicinity of the upper ends of the heat radiation fins 37b, the upward flow of the air flowing into the region Sb is less likely to be hindered, and thus the heat radiation performance is less likely to be hindered.

Similarly, air flowing upward through the gaps between the heat radiation fins 37c may be hindered from flowing upward from the upper ends of the heat radiation fins 37c due to collision with the bolt attachment portion 34b or the like. In this regard, in the present example as described above, the region Sc between the three heat radiation fins 37c and the bolt attachment portion 34b has an increasing interval in the upper-lower direction from the right end toward the left end of the bolt attachment portion 34b in the left-right direction. For this reason, when air flowing upward through the gaps between the heat radiation fins 37c flows into the region Sc, pressure in a part where the interval of the region Sc in the upper-lower direction is large is generally lower than pressure in a part where the interval of the region Sc in the upper-lower direction is small, and thus the air flows toward a region where the interval of the region Sc in the upper-lower direction is larger. Specifically, the air flowing into the region Sc does not flow to simply collide with the bolt attachment portion 34b, but is guided to flow around the left end of the bolt attachment portion 34b as indicated by white arrows in the drawing. For this reason, even when the bolt attachment portion 34b is present in a vicinity of the upper ends of the heat radiation fins 37c, the upward flow of the air flowing into the region Sc is less likely to be hindered, and thus the heat radiation performance is less likely to be hindered.

### Operations and Effects

As described above, according to the heat radiation body (case 30) and the box-shaped body 1 in the present embodiment, intervals between at least a part of the plurality of heat radiation fins 37a, 37b, and 37c (that is, two or more heat radiation fins 37a, 37b, and 37c) and walls (seat portion 35 and bolt attachment portions 34a and 34b) adjacent to the heat radiation fins 37a, 37b, and 37c in an extending direction (upper-lower direction) in which the plurality of heat radiation fins 37a, 37b, and 37c extend increase toward one ends of the walls 35, 34a and 34b in an intersecting direction (left-right direction). Accordingly, when air flows from a flow path between the two or more heat radiation fins 37a, 37b, and 37c to the regions

Sa, Sb, and Sc between the heat radiation fins 37a, 37b, and 37c and the walls 35, 34a and 34b, pressure in the region having a large “interval” is generally lower than pressure in the region having a small “interval”, and thus the air flows toward the region having the large “interval” (that is, toward one ends of the walls 35, 34a and 34b). In other words, the air does not flow to simply collide with the walls 35, 34a and 34b, but is guided to flow around one ends of the walls 35, 34a and 34b. For this reason, even when the walls 35, 34a and 34b are present in a vicinity of the heat radiation fins 37a, 37b, and 37c, the flow of air is less likely to be hindered. Therefore, as in the present example, even when the walls used for the seat portion 35, which fixes the power input terminal 36, and the bolt attachment portions 34a and 34b are in close contact with the heat radiation fins 37a, 37b, and 37c, heat can be efficiently dissipated from the heat radiation fins 37a, 37b, and 37c. Therefore, the heat radiation body 30 and the box-shaped body 1 according to the present embodiment have an excellent heat radiation performance.

Further, two or more heat radiation fins 37a are configured such that the above-described interval increases from a central portion toward one end of the wall 35, and the other two or more heat radiation fins 37a are configured such that the above-described interval increases from the central portion toward the other end of the wall 35. Accordingly, air flowing into the region between the heat radiation fins 37a and the wall 35 is divided and guided into a flow going around one end of the wall 35 and a flow going around the other end of the wall 35. Therefore, the air can flow more smoothly compared to a case where all air is guided to go around one end of the wall 35, and thus the heat radiation performance of the heat radiation body 30 can be further improved.

Further, another wall (bolt attachment portion 34a) is present in a position adjacent to the wall (seat portion 35) in a direction (left-right direction) intersecting the extending direction of the heat radiation fins 37a, 37b, and 37c. Accordingly, even when air flowing along the heat radiation fins 37a is difficult to flow around the wall 35, the air is guided to flow around one ends of the walls 35 and 34a, and thereby the heat radiation performance of the heat radiation body 30 can be improved.

### Other Embodiments

The present disclosure is not limited to the embodiment described above and various modifications can be adopted within the scope of the present disclosure. For example, the present disclosure is not limited to the embodiment described above, and modifications, improvements, and the like can be appropriately made. In addition, materials, shapes, sizes, numbers, arrangement positions, and the like of components in the embodiment described above are freely selected and are not limited as long as the present disclosure can be implemented.

For example, as illustrated in FIG. 5 in the above embodiment, lengths of the heat radiation fins 37a in the upper-lower direction decrease toward the left and right ends of the wall 35, so that the interval of the region Sa in the upper-lower direction increases. In contrast, the heat radiation fins 37a and the wall 35 may be configured such that the heat radiation fins 37a have the same length, and the lower face of the wall 35 is inclined to be far away from the heat radiation fins 37a toward the left and right ends of the wall 35, so that the interval of the region Sa in the upper-lower direction increases.

Here, features of the embodiment of the heat radiation body 30 and the box-shaped body 1 according to the present disclosure described above are briefly summarized and listed in the following [1] to [6].

[1] A heat radiation body (30) that radiates heat generated by a heat source, the heat radiation body (30) including:
a base portion (32) to which the heat is transferred; a plurality of heat radiation fins (37a, 37b, 37c) provided on the base portion (32) and extending in a prescribed extending direction; and a wall (35, 34a, 34b) adjacent to the plurality of heat radiation fins (37a, 37b, 37c) in the extending direction, in which
the plurality of heat radiation fins (37a, 37b, 37c) includes two or more heat radiation fins (37a, 37b, 37c) configured such that an interval between the heat radiation fins (37a, 37b, 37c) and the wall (35, 34a, 34b) in the extending direction increases toward one end of the wall (35, 34a, 34b) in an intersecting direction intersecting the extending direction.

According to the heat radiation body having the configuration [1], the interval between the wall adjacent to the plurality of heat radiation fins and at least a part of the plurality of heat radiation fins (that is, two or more heat radiation fins) increases toward one end of the wall. Accordingly, when air flows from a flow path between the two or more heat radiation fins to the region between the wall and the two or more heat radiation fins, pressure in a region having a large interval is generally lower than pressure in a region having a small interval. Accordingly, the air flows from the region having a small interval toward the region having a large interval (that is, toward one end of the wall). In other words, the air does not flow to simply collide with the wall, but is guided to flow around one end of the wall. For this reason, even when the wall is present in a vicinity of the heat radiation fins, the flow of air is less likely to be hindered by the wall. Therefore, for example, even when a wall used for a seat portion or the like for fixing a power input terminal and the heat radiation fins are integrally provided on the base portion and are in close contact with each other, heat can be efficiently dissipated from the heat radiation fins. Therefore, the heat radiation body having the present configuration has an excellent heat radiation performance.

[2] The heat radiation body (30) according to [1], in which
the plurality of heat radiation fins (37a) include two or more heat radiation fins (37a) configured such that the interval increases from a central portion toward the one end of the wall (35) in the intersecting direction, and other two or more heat radiation fins (37a) configured such that the interval increases from the central portion toward another end of the wall (35) in the intersecting direction.

According to the heat radiation body having the configuration [2], the two or more heat radiation fins are configured such that the interval increases from a central portion toward the one end of the wall, and the other two or more heat radiation fins are configured such that the interval increases from the central portion toward another end of the wall. Accordingly, the air flowing into the region between the heat radiation fins and the wall is divided and guided into a flow going around one end of the wall and a flow going around the other end of the wall. Therefore, the air can flow more smoothly compared to a case where all air is guided to go around either end of the wall, and thus the heat radiation performance of the heat radiation body can be further improved.

[3] The heat radiation body (30) according to [1], further including:
another wall (34a) in a position adjacent to the wall (35) in the intersecting direction.

According to the heat radiation body having the configuration [3], even when air flowing along the heat radiation fins is difficult to flow around the wall due to presence of another wall in a position adjacent to the wall, the heat radiation performance of the heat radiation body can be improved by the air passing through a through hole of the wall.

[4] A box-shaped body (1) for accommodating a heat source in an internal space, the box-shaped body (1) including:
the heat radiation body (30) according to any one of [1] to [3] as at least a part of an outer wall of the box-shaped body (1).

According to the box-shaped body having the configuration [4], the heat radiation body is provided as at least a part of an outer wall of the box-shaped body. Accordingly, heat generated by the heat source inside the box-shaped body can be efficiently radiated to outside of the box-shaped body. Therefore, the box-shaped body having this configuration has an excellent heat radiation performance.

[5] The box-shaped body (1) according to [4], in which
the wall of the heat radiation body (30) is a seat portion (35) configured to fix a terminal (36) electrically connecting inside and outside of the box-shaped body (1).

According to the box-shaped body having the configuration [5], the wall of the heat radiation body is used as a seat portion to fix a terminal electrically connecting inside and outside of the box-shaped body. Accordingly, the seat portion is less likely to hinder heat radiation.

[6] The box-shaped body (1) according to [4], further including:
a case (30) and a cover (20) that define the internal space, in which
the wall of the heat radiation body (30) is an attachment portion (34a, 34b) allowing a fixing tool for fixing the cover (20) to the case (30) to be attached.

According to the box-shaped body having the configuration [6], the wall of the heat radiation body is used as an attachment portion allowing a fixing tool for fixing the case and the cover constituting the box-shaped body to be attached. For example, when a bolt is used as the fixing tool, even when an attachment portion for providing a bolt fastening hole is provided in a vicinity of the heat radiation fins, the attachment portion is less likely to hinder heat radiation.

1. A heat radiation body that radiates heat generated by a heat source, the heat radiation body comprising:
a base portion to which the heat is transferred; a plurality of heat radiation fins provided on the base portion and extending in a prescribed extending direction; and a wall adjacent to the plurality of heat radiation fins in the extending direction, wherein
the plurality of heat radiation fins includes two or more heat radiation fins configured such that an interval between the heat radiation fins and the wall in the extending direction increases toward one end of the wall in an intersecting direction intersecting the extending direction.

2. The heat radiation body according to claim 1, wherein
the plurality of heat radiation fins include two or more heat radiation fins configured such that the interval increases from a central portion toward the one end of the wall in the intersecting direction, and other two or more heat radiation fins configured such that the interval increases from the central portion toward another end of the wall in the intersecting direction.

3. The heat radiation body according to claim 1, further comprising:
another wall in a position adjacent to the wall in the intersecting direction.

4. A box-shaped body for accommodating a heat source in an internal space, the box-shaped body comprising:
the heat radiation body according to claim 1 as at least a part of an outer wall of the box-shaped body.

5. The box-shaped body according to claim 4, wherein
the wall of the heat radiation body is a seat portion configured to fix a terminal electrically connecting inside and outside of the box-shaped body.

6. The box-shaped body according to claim 4, further comprising:
a case and a cover that define the internal space, wherein
the wall of the heat radiation body is an attachment portion allowing a fixing tool for fixing the cover to the case to be attached.
